(19) United States
(12) Patent Application Publication
(10) Pub. No.: US 2026/0017422 A1
(43) Pub. Date: Jan. 15, 2026

(54) METHODS FOR REFINING TOPOLOGY OPTIMIZED DESIGNS OF STRUCTURES AND NON-TRANSITORY COMPUTER-READABLE MEDIA ASSOCIATED THEREWITH

(71) Applicant: The Boeing Company, Arlington, VA (US)

(72) Inventor: Brian S. Smith, Charleston, SC (US)

(73) Assignee: The Boeing Company, Arlington, VA (US)

(21) Appl. No.: 18/768,623

(22) Filed: Jul. 10, 2024

(51) Int. Cl. G06F 30/15

(52) U.S. Cl. CPC G06F 30/15

(57) ABSTRACT

A method for refining a topology optimized design of a structure includes receiving a source image file representative of the topology optimized design for the structure at a latent space diffusion model with a network control extension, generating a natural language conditioning prompt to describe desired content for a refined design of the structure, preprocessing the source image file at the network control extension using feature extraction tools to extract image features from the source image file, generating a conditioning image file at the network control extension, applying the natural language conditioning prompt, the conditioning image file and a series of noisy image files to a neural network of the latent space diffusion model, and processing the natural language conditioning prompt, the conditioning image file and the series of noisy image files through the neural network using a reverse diffusion process to create an intermediate generative image file.

### FIELD

The present disclosure relates generally to refining topology optimized designs of structures and, particularly, to implementing generative artificial intelligence techniques on such designs. Such refinements on topology optimized designs can improve the design process for complex structures. Generative artificial intelligence techniques present opportunities for improving top-down designs of structures, assemblies, subassemblies and parts with an emphasis on manufacturability, weight savings and various other cost and performance features.

### BACKGROUND

Topology optimization is a mathematical method that optimizes material layout within a given design space, for a given set of loads, boundary conditions and constraints with the goal of maximizing the performance of the system. The conventional topology optimization formulation uses a finite element method to evaluate the design performance. The design is optimized using either gradient-based mathematical programming techniques such as the optimality criteria algorithm and the method of moving asymptotes or non-gradient-based algorithms such as genetic algorithms. Topology optimization has a wide range of applications in aerospace, mechanical, bio-chemical and civil engineering. Currently, engineers mostly use topology optimization at the concept level of a design process. Due to the free forms that naturally occur, the result is often difficult to manufacture. For that reason, the result emerging from topology optimization is often fine-tuned for manufacturability. Adding constraints to the formulation in order to increase the manufacturability is an active field of research.

Accordingly, those skilled in the art continue with research and development efforts to introduce new techniques for refining topology optimized designs of structures with particular attention to manufacturability.

### SUMMARY

Disclosed are examples of methods for refining topology optimized designs of structures and non-transitory computer-readable media associated therewith. The following is a non-exhaustive list of examples, which may or may not be claimed, of the subject matter according to the present disclosure.

In an example, the disclosed method for refining a topology optimized design of a structure includes: (1) receiving a source image file representative of the topology optimized design for the structure at a latent space diffusion model with a network control extension; (2) generating a natural language conditioning prompt to describe desired content for a refined design of the structure based on the topology optimized design; (3) preprocessing the source image file at the network control extension using feature extraction tools to extract image features from the source image file; (4) generating a conditioning image file at the network control extension based on the image features extracted from the source image file; (5) applying the natural language conditioning prompt, the conditioning image file and a series of noisy image files to a neural network of the latent space diffusion model; and (6) processing the natural language conditioning prompt, the conditioning image file and the series of noisy image files through the neural network using a reverse diffusion process to create an intermediate generative image file.

In another example, the disclosed method for refining a topology optimized design of a structure includes: (1) receiving a source image file representative of the topology optimized design for the structure at a latent space diffusion model with a network control extension; (2) generating a natural language conditioning prompt to describe desired content for a refined design of the structure based on the topology optimized design; (3) preprocessing the source image file at the network control extension using feature extraction tools to extract at least one image feature from the source image file; (4) generating a conditioning image file at the network control extension based on the at least one image feature extracted from the source image file; (5) applying the natural language conditioning prompt, the conditioning image file and a series of noisy image files to a neural network of the latent space diffusion model, wherein the series of noisy image files is related to the source image file; and (6) processing the natural language conditioning prompt (2010), the conditioning image file (2014) and the series of noisy image files (2016) through the neural network using a reverse diffusion process to create an intermediate generative image file.

In an example, the disclosed non-transitory computer-readable medium includes program instructions that, when executed by at least one processor, cause at least one computing device to perform a method for refining a topology optimized design of a structure. In an example, the method includes: (1) receiving a source image file representative of the topology optimized design for the structure at a latent space diffusion model with a network control extension; (2) generating a natural language conditioning prompt to describe desired content for a refined design of the structure based on the topology optimized design; (3) preprocessing the source image file at the network control extension using feature extraction tools to extract image features from the source image file; (4) generating a conditioning image file at the network control extension based on the image features extracted from the source image file; (5) applying the natural language conditioning prompt, the conditioning image file and a series of noisy image files to a neural network of the latent space diffusion model; and (6) processing the natural language conditioning prompt, the conditioning image file and the series of noisy image files through the neural network using a reverse diffusion process to create an intermediate generative image file.

Other examples of the disclosed methods for refining topology optimized designs of structures and non-transitory computer-readable media associated therewith will become apparent from the following detailed description, the accompanying drawings and the appended claims.

### BRIEF DESCRIPTION OF THE DRAWINGS

FIG. 1 is a flow diagram of an example of a method for refining a topology optimized design of a structure;

FIG. 2 is a top view of an example of a structure;

FIG. 3, in combination with FIG. 1, is a flow diagram of another example of a method for refining a topology optimized design of a structure;

FIG. 4, in combination with FIG. 1, is a flow diagram of yet another example of a method for refining a topology optimized design of a structure;

FIG. 5, in combination with FIG. 1, is a flow diagram of still another example of a method for refining a topology optimized design of a structure;

FIG. 6, in combination with FIG. 1, is a flow diagram of still yet another example of a method for refining a topology optimized design of a structure;

FIG. 7, in combination with FIG. 1, is a flow diagram of another example of a method for refining a topology optimized design of a structure;

FIG. 8 is a flow diagram of yet another example of a method for refining a topology optimized design of a structure;

FIG. 9, in combination with FIG. 8, is a flow diagram of still another example of a method for refining a topology optimized design of a structure;

FIG. 10, in combination with FIGS. 8 and 9, is a flow diagram of still yet another example of a method for refining a topology optimized design of a structure;

FIG. 11, in combination with FIGS. 8-10, is a flow diagram of still yet another example of a method for refining a topology optimized design of a structure;

FIG. 12, in combination with FIGS. 8-11, is a flow diagram of another example of a method for refining a topology optimized design of a structure;

FIG. 13, in combination with FIGS. 8-12, is a flow diagram of yet another example of a method for refining a topology optimized design of a structure;

FIG. 14, in combination with FIGS. 8-13, is a flow diagram of still another example of a method for refining a topology optimized design of a structure;

FIG. 15, in combination with FIGS. 8-14, is a flow diagram of another example of a method for refining a topology optimized design of a structure;

FIG. 16, in combination with FIG. 8, is a flow diagram of yet another example of a method for refining a topology optimized design of a structure;

FIG. 17, in combination with FIG. 8, is a flow diagram of still another example of a method for refining a topology optimized design of a structure;

FIG. 18, in combination with FIG. 8, is a flow diagram of still yet another example of a method for refining a topology optimized design of a structure;

FIG. 19 is a block diagram of an example of a non-transitory computer-readable medium associated with the methods of FIGS. 1 and 3-19;

FIG. 20 is a block diagram of an example of a computerized system for refining a topology optimized design of a structure;

FIG. 21, in combination with FIG. 1, is a flow diagram of another example of a method for refining a topology optimized design of a structure;

FIG. 22, in combination with FIG. 1, is a flow diagram of yet another example of a method for refining a topology optimized design of a structure;

FIG. 23, in combination with FIG. 1, is a flow diagram of still another example of a method for refining a topology optimized design of a structure;

FIG. 24 is a block diagram of aircraft production and service methodology that implements one or more of the examples of methods for refining a topology optimized design of a structure disclosed herein; and

FIG. 25 is a schematic illustration of an aircraft that incorporates structures that are designed using one or more of the examples of methods for refining a topology optimized design of a structure disclosed herein disclosed herein.

### DETAILED DESCRIPTION

Various examples of methods for refining topology optimized designs of structures are disclosed herein. Various examples of non-transitory computer-readable media associated with the methods are also disclosed herein. The various examples implement generative artificial intelligence techniques on the topology optimized designs to take advantage of the weight savings from topology optimized design tools and improve manufacturability of the topology optimized designs. The generative artificial intelligence techniques also improve top-down designs of the structure, assemblies, subassemblies and parts.

The generative artificial intelligence techniques includes use of a latent space diffusion model with a network control extension to address the challenges associated with interpreting and manufacturing complex outputs from topology optimization algorithms. Topology optimization outputs often result in intricate structures that are difficult to manufacture and lack practical joints. The methods disclosed herein aim to bridge the gap between the complex outputs of topology optimization and the need for manufacturability, discrete part splitting, and realistic joints. By leveraging the power of latent space diffusion models, the methods for refining topology optimized designs for structure provide solutions that allow designers to interpret and transform the topology optimization outputs into manufacturable parts while preserving the weight savings achieved through the optimization process.

Existing solutions for interpreting and manufacturing complex outputs from topology optimization algorithms typically involve manual interpretation and redesign by experienced engineers. These engineers analyze the output structures and manually modify them to make them manufacturable and incorporate realistic joints. However, this process is time-consuming, labor-intensive, and highly dependent on the expertise of the engineers. It also lacks a systematic approach and may result in suboptimal designs or loss of weight savings achieved through topology optimization.

The various methods for refining topology optimized designs of structure utilizes a latent space diffusion model, which is a generative model capable of capturing the underlying structure or patterns in the topology optimization outputs and mapping them to existing structures and concepts which exist in the real world. This model maps the complex outputs into a lower-dimensional latent space, where similar data points are closer together. The latent space diffusion model incorporates a network control extension that allows for fine-grained control over the generation process. By manipulating the latent variables or input parameters of the model, designers can guide the generation of discrete parts with realistic joints while maintaining the overall structure of the topology optimization. Most importantly, the network control extension prevents the latent space diffusion model from conceptually drifting from the topology optimized solution.

Unlike manual interpretation of topology optimized designs, the methods disclosed herein offer an automated approach to interpret complex outputs from topology optimization algorithms. By utilizing a latent space diffusion model, the various methods systematically analyze and understand the intricate structures, reducing the reliance on manual expertise and saving time.

The incorporation of the network control extension allows for fine-grained control over the generation process, enabling designers to manipulate latent variables and input parameters to guide the generation of discrete parts with realistic joints. This level of control was not present in previous manual techniques for interpretation of topology optimized designs.

The various methods for refining topology optimized designs provide the capability to split the optimized structure into discrete parts. This enhances manufacturability by allowing designers to create parts that can be manufactured separately and assembled later. Prior solutions often lacked this flexibility, resulting in challenges during the manufacturing process. The various methods also address the need for realistic joint incorporation, which was often overlooked in prior solutions. By considering practical joints in the generated parts, the methods ensure proper assembly and functionality, making the resulting design more practical and usable. This methods explicitly focus on preserving the weight savings achieved through topology optimization. By leveraging the latent space diffusion model with the network control extension, the generated parts maintain the structural efficiency while being manufacturable. Prior solutions may not have explicitly addressed this aspect, leading to compromised weight savings or suboptimal designs.

The various methods of refining topology optimized designs of structures are capable of interpreting structure represented in two dimensional images and/or three-dimensional models, allowing users to utilize the methods with any part that can be topology optimized. The methods utilize natural language inputs via the latent space diffusion model, allowing users to steer the generation process towards parts that better suit their vision. The methods can be utilized in the design and manufacture of lightweight and complex structures. The methods can also be used to optimize the design of structures by applying topology optimization algorithms. The methods ensure that the resulting optimized structures maintain weight savings while being manufacturable. The methods aid in the interpretation of complex topology optimization outputs. Designers can use the automated interpretation capabilities to understand the intricate structures and identify areas that require modification for manufacturability. This helps streamline the design process and reduces the reliance on manual interpretation.

The various methods for refining topology optimized designs of structures allow for the splitting of the optimized structure into discrete parts and the incorporation of realistic joints. Companies or suppliers can utilize this feature to create designs that can be manufactured separately and assembled later, enhancing the manufacturability and flexibility of the final product. The methods facilitate collaboration between design, stress analysis, and manufacturing teams. Designers can generate designs that are optimized for weight savings and manufacturability, providing manufacturing teams with clear instructions for producing the parts. Incorporation of realistic joints and manufacturable components also allows for analysis of structure using established stress analysis products. This collaboration ensures that the final product maintains the desired structural integrity while being feasible to analyze and manufacture.

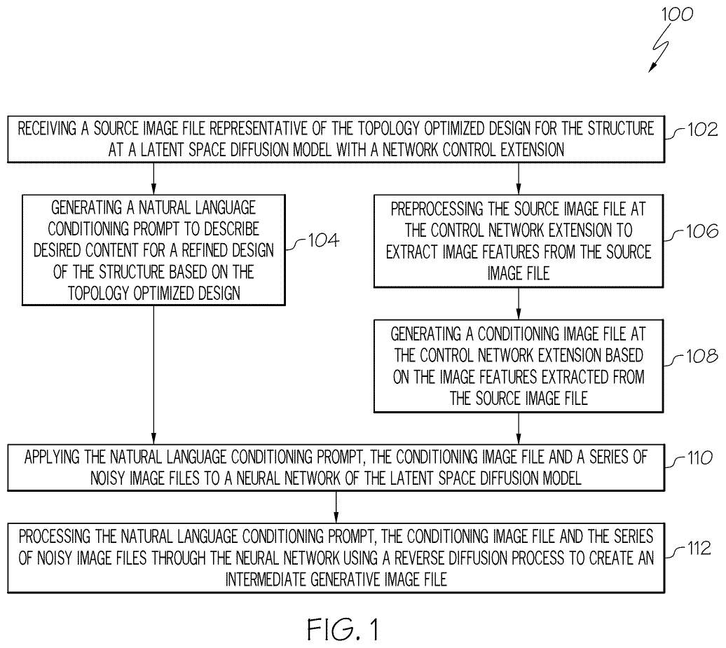

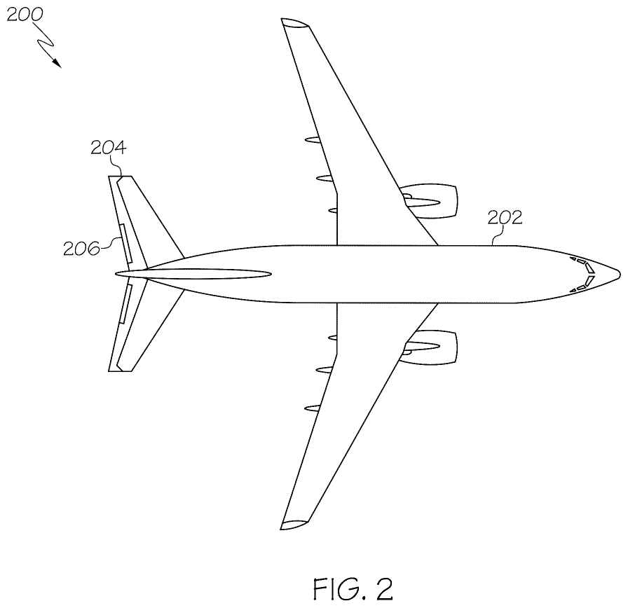

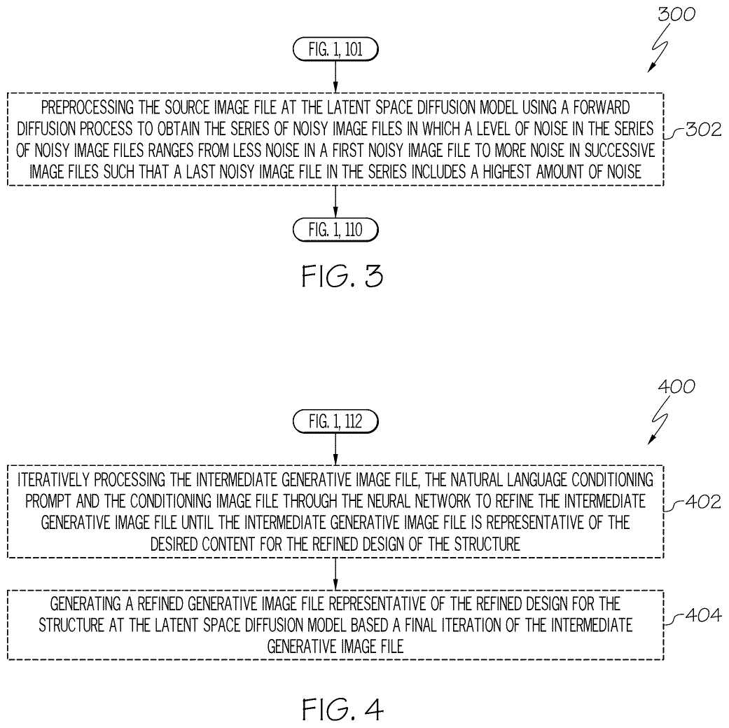

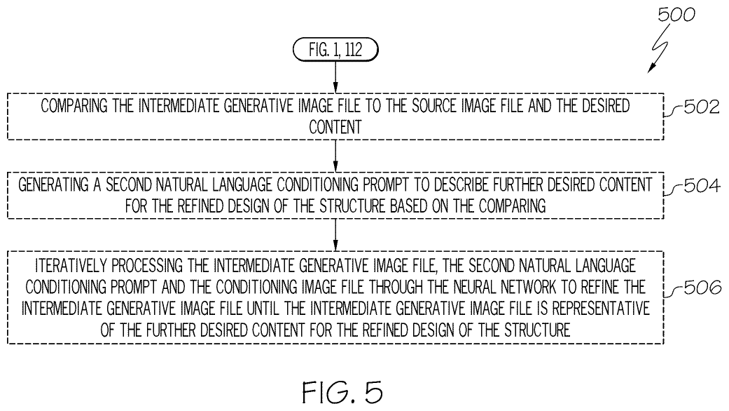

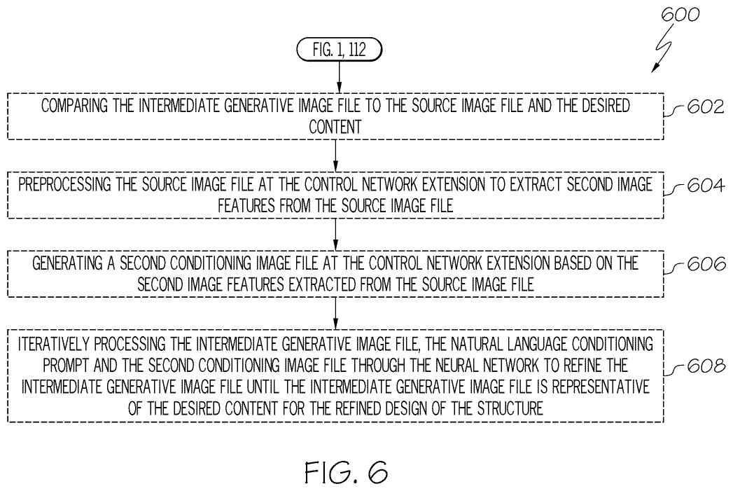

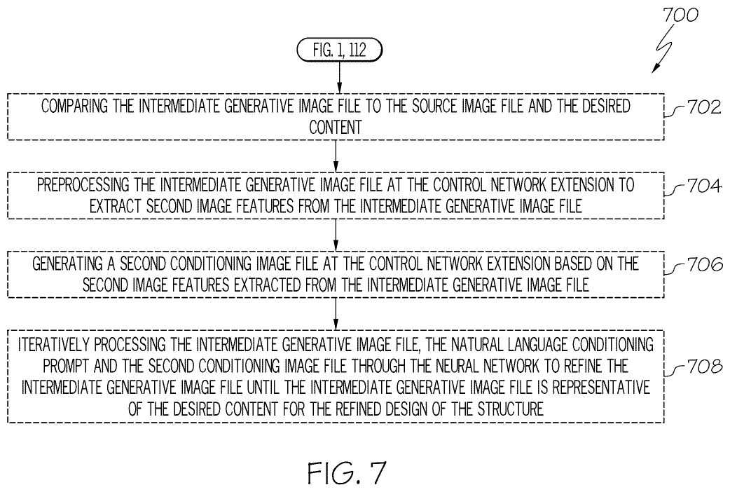

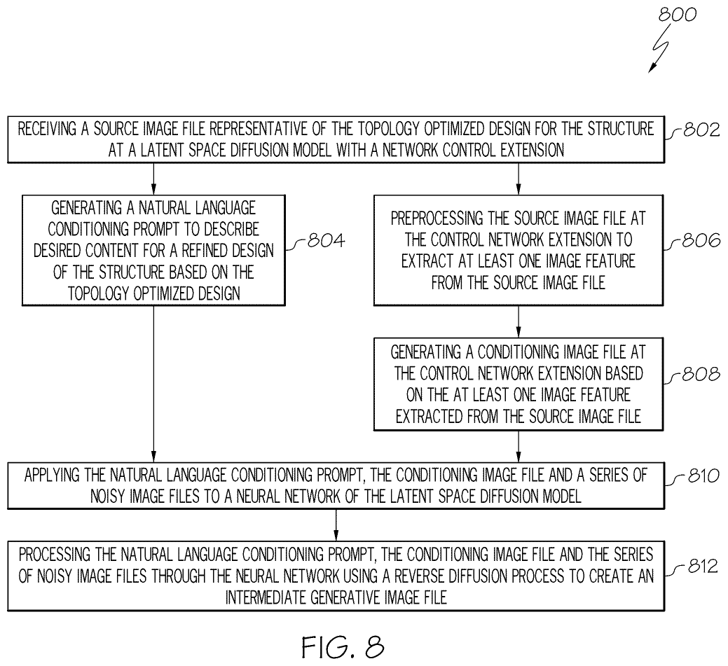

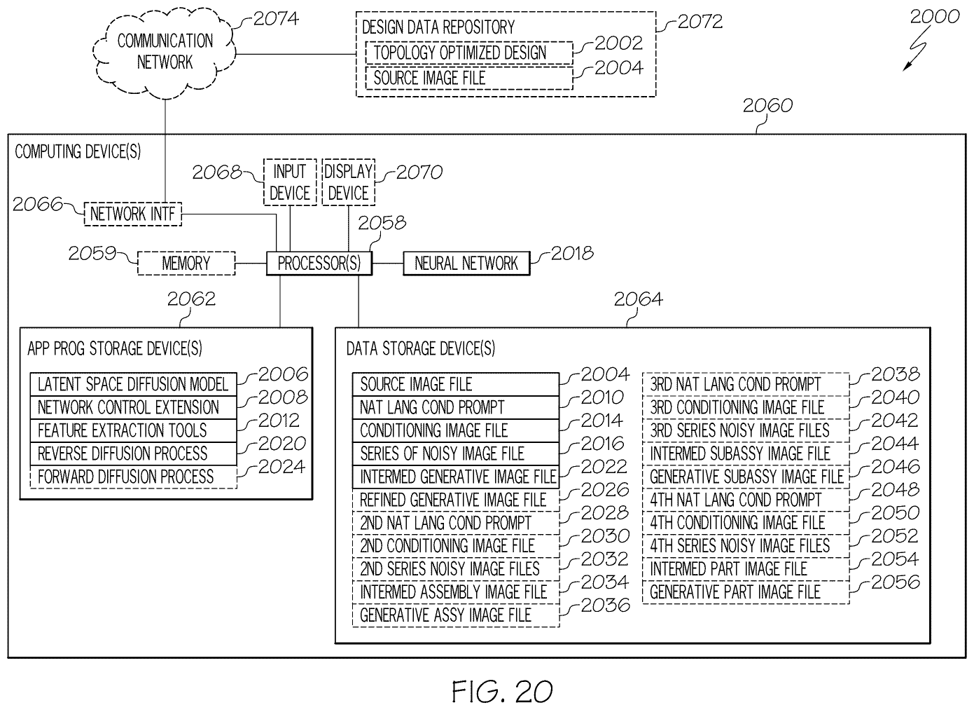

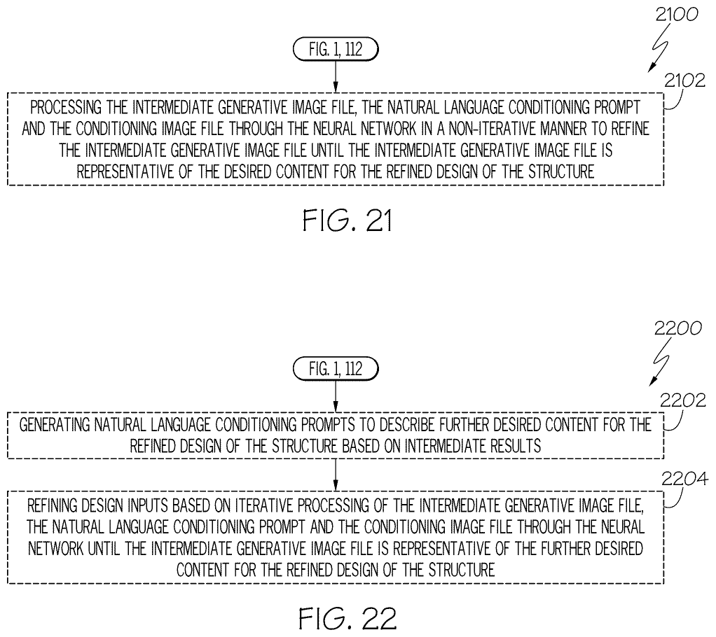

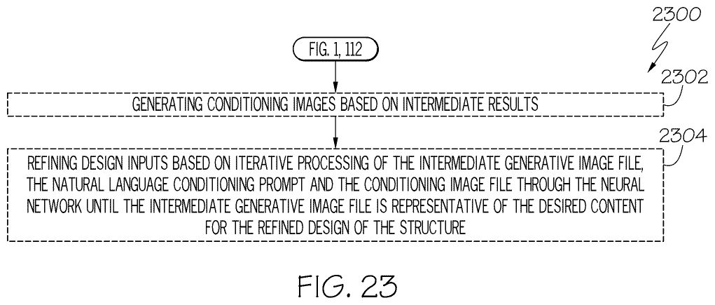

Referring generally to FIGS. 1-7 and 20-23, by way of examples, the present disclosure is directed to a method 100, 300, 400, 500, 600, 700, 2100, 2200, 2300 for refining a topology optimized design 2002 of a structure 200. FIG. 1 provides an example of the method 100 for refining the topology optimized design 2002 of the structure 200. FIG. 2 is a top view of an example of the structure 200. FIG. 3, in combination with FIG. 1, provides an example of the method 300. FIG. 4, in combination with FIG. 1, provides an example of the method 400. FIG. 5, in combination with FIG. 1, provides an example of the method 500. FIG. 6, in combination with FIG. 1, provides an example of the method 600. FIG. 7, in combination with FIG. 1, provides an example of the method 700. FIG. 20 is a block diagram of an example of a computerized system 2000 for refining the topology optimized design 2002 of the structure 200. FIG. 21, in combination with FIG. 1, provides an example of the method 2100. FIG. 22, in combination with FIG. 1, provides an example of the method 2200. FIG. 23, in combination with FIG. 1, provides an example of the method 2300.

With reference again to FIGS. 1, 2 and 20, in one or more examples, a method 100 (see FIG. 1) for refining a topology optimized design 2002 of a structure 200 includes receiving 102 a source image file 2004 representative of the topology optimized design 2002 for the structure 200 at a latent space diffusion model 2006 with a network control extension 2008. At 104, a natural language conditioning prompt 2010 is generated to describe desired content for a refined design of the structure 200 based on the topology optimized design 2002. At 106, the source image file 2004 is preprocessed at the network control extension 2008 using feature extraction tools 2012 to extract image features from the source image file 2004. At 108, a conditioning image file 2014 is generated at the network control extension 2008 based on the image features extracted from the source image file 2004. At 110, the natural language conditioning prompt 2010, the conditioning image file 2014 and a series of noisy image files 2016 are applied to a neural network 2018 of the latent space diffusion model 2006. At 112, the natural language conditioning prompt 2010, the conditioning image file 2014 and the series of noisy image files 2016 are processed through the neural network 2018 using a reverse diffusion process 2020 to create an intermediate generative image file 2022.

In another example of the method 100, the source image file 2004 includes a two-dimensional view of the structure 200. In a further example, the two-dimensional view includes an external view of the structure 200, a sectional view of the structure 200, a cross-sectional view of the structure 200, a truncated view of the structure 200 or any other suitable two-dimensional view in any suitable combination. In another further example, the two-dimensional view includes any view of the structure 200, including, but not limited to, an external view, a sectional view, a cross-sectional view and a truncated view. In yet another example of the method 100, the topology optimized design 2002 includes a three-dimensional model of the structure 200. In a further example, the three-dimensional model of the structure 200 includes a computer-aided design model, a wireframe model, a surface model, a textured surface model or any other suitable three-dimensional model. In another further example, the three-dimensional model of the structure 200 includes any type of three-dimensional representation, including, but not limited to, a computer-aided design model, a wireframe model, a surface model and a textured surface model.

In still another example of the method 100, the image features include pose features, background features, foreground features, depth features, edge features, line features, straight-line features, object features, texture features, color features, transparency features or any other suitable image features in any suitable combination. In still yet another example of the method 100, the image features include any type of visual characteristic or attribute of an image. In another example of the method 100, the conditioning image file 2014 includes a two-dimensional image. In yet another example of the method 100, the series of noisy image files 2016 are obtained from the source image file 2004 by adding a predetermined amount of noise to a first noisy image file and adding more noise to successive image files in the series such that a last noisy image file in the series includes a highest amount of noise. In another example of the method 100, the intermediate generative image file 2022 includes a two-dimensional view of the structure 200.

With reference again to FIG. 2, the structure 200 includes an assembly 202, a subassembly 204 and a part 206. As shown in the drawing, a commercial aircraft is an example of the structure 200. A horizontal stabilizer is an example of the assembly 202. An elevator is an example of the subassembly 204. A bracket or spar in the horizonal stabilizer is an example of the part 206.

With reference again to FIGS. 1-3 and 20, in one or more examples, a method 300 (see FIG. 3) for refining a topology optimized design 2002 of a structure 200 includes the method 100 of FIG. 1 and continues from 102 to 302 where the source image file 2004 is preprocessed at the latent space diffusion model 2006 using a forward diffusion process 2024 to obtain the series of noisy image files 2016 in which a level of noise in the series of noisy image files 2016 ranges from less noise in a first noisy image file to more noise in successive image files such that a last noisy image file in the series includes a highest amount of noise. The method 300 continues from 302 to 110 of FIG. 1.

With reference again to FIGS. 1, 2, 4 and 20, in one or more examples, a method 400 (see FIG. 4) for refining a topology optimized design 2002 of a structure 200 includes the method 100 of FIG. 1 and continues from 112 to 402 where the intermediate generative image file 2022, the natural language conditioning prompt 2010 and the conditioning image file 2014 are iteratively processed through the neural network 2018 to refine the intermediate generative image file 2022 until the intermediate generative image file 2022 is representative of the desired content for the refined design of the structure 200. In another example, the method 400 also includes generating 404 a refined generative image file 2026 representative of the refined design for the structure 200 at the latent space diffusion model 2006 based on a final iteration of the intermediate generative image file 2022. In a further example, the refined generative image file 2026 includes a two-dimensional view of the structure 200. In another further example, manufacturability of the refined design for the structure 200 is enhanced over that of the topology optimized design 2002 for the structure 200. In yet another further example, the refined design of the structure 200 retains weight savings introduced in the topology optimized design 2002 of the structure 200. In still another further example, the refined generative image file 2026 includes an exploded view of the structure 200 that shows at least two parts 206 used to fabricate the structure 200 in a disassembled representation. In still yet another further example, the refined generative image file 2026 includes a two-dimensional view of a part 206 used to fabricate the structure 200. In another further example, the refined generative image file 2026 includes a two-dimensional view of the structure 200 enhanced to show realistic joints.

With reference again to FIGS. 1, 2, 20 and 21, in one or more examples, a method 2100 (see FIG. 21) for refining a topology optimized design 2002 of a structure 200 includes the method 100 of FIG. 1 and continues from 112 to 2102 where the intermediate generative image file 2022, the natural language conditioning prompt 2010 and the conditioning image file 2014 are processed through the neural network 2018 in a non-iterative manner to refine the intermediate generative image file 2022 until the intermediate generative image file 2022 is representative of the desired content for the refined design of the structure 200.

With reference again to FIGS. 1, 2, 5 and 20, in one or more examples, a method 500 (see FIG. 5) for refining a topology optimized design 2002 of a structure 200 includes the method 100 of FIG. 1 and continues from 112 to 502 where the intermediate generative image file 2022 is compared to the source image file 2004 and the desired content. At 504, a second natural language conditioning prompt 2028 is generated to describe further desired content for the refined design of the structure 200 based on the comparing 502. At 506, the intermediate generative image file 2022, the second natural language conditioning prompt 2028 and the conditioning image file 2014 are iteratively processed through the neural network 2018 to refine the intermediate generative image file 2022 until the intermediate generative image file 2022 is representative of the further desired content for the refined design of the structure 200.

With reference again to FIGS. 1, 2, 20 and 22, in one or more examples, a method 2200 (see FIG. 22) for refining a topology optimized design 2002 of a structure 200 includes the method 100 of FIG. 1 and continues from 112 to 2202 where natural language conditioning prompts are generated to describe further desired content for the refined design of the structure 200 based on intermediate results. At 2204, design inputs are refined based on iterative processing of the intermediate generative image file 2022, the natural language conditioning prompt 2010 and the conditioning image file 2014 through the neural network 2018 until the intermediate generative image file 2022 is representative of the further desired content for the refined design of the structure 200.

With reference again to FIGS. 1, 2, 6 and 20, in one or more examples, a method 600 (see FIG. 6) for refining a topology optimized design 2002 of a structure 200 includes the method 100 of FIG. 1 and continues from 112 to 602 where the intermediate generative image file 2022 is compared to the source image file 2004 and the desired content. At 604, the source image file 2004 is preprocessed at the network control extension 2008 using the feature extraction tools 2012 to extract second image features from the source image file 2004. At 606, a second conditioning image file 2030 is generated at the network control extension 2008 based on the second image features extracted from the source image file 2004. At 608, the intermediate generative image file 2022, the natural language conditioning prompt 2010 and the second conditioning image file 2030 are iteratively processed through the neural network 2018 to refine the intermediate generative image file 2022 until the intermediate generative image file 2022 is representative of the desired content for the refined design of the structure 200.

With reference again to FIGS. 1, 2, 20 and 23, in one or more examples, a method 2300 (see FIG. 23) for refining a topology optimized design 2002 of a structure 200 includes the method 100 of FIG. 1 and continues from 112 to 2302 where conditioning images are generated based on intermediate results. At 2304, design inputs are refined based on iterative processing of the intermediate generative image file 2022, the natural language conditioning prompt 2010 and the conditioning image file 2014 through the neural network 2018 until the intermediate generative image file 2022 is representative of the desired content for the refined design of the structure 200.

With reference again to FIGS. 1, 2, 7 and 20, in one or more examples, a method 700 (see FIG. 7) for refining a topology optimized design 2002 of a structure 200 includes the method 100 of FIG. 1 and continues from 112 to 702 where the intermediate generative image file 2022 is compared to the source image file (2004) and the desired content. At 704, the intermediate generative image file 2022 is processed at the network control extension 2008 using the feature extraction tools 2012 to extract second image features from the intermediate generative image file 2022. At 706, a second conditioning image file 2030 is generated at the network control extension 2008 based on the second image features extracted from the intermediate generative image file 2022. At 708, the intermediate generative image file 2022, the natural language conditioning prompt 2010 and the second conditioning image file 2030 are iteratively processed through the neural network 2018 to refine the intermediate generative image file 2022 until the intermediate generative image file 2022 is representative of the desired content for the refined design of the structure 200.

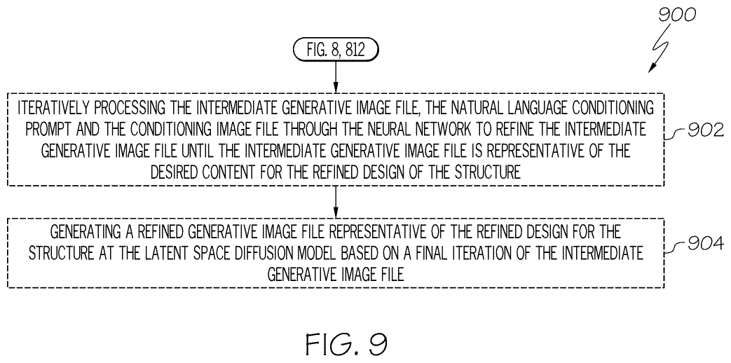

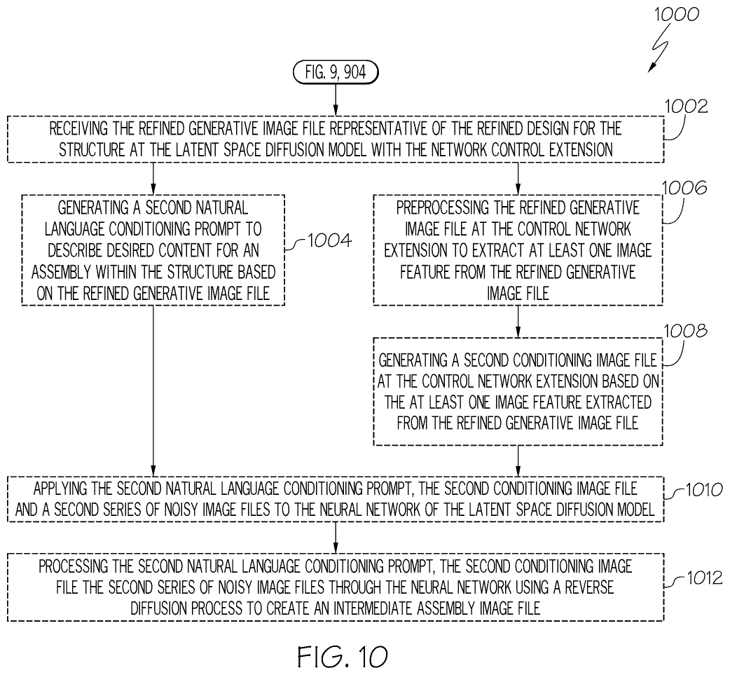

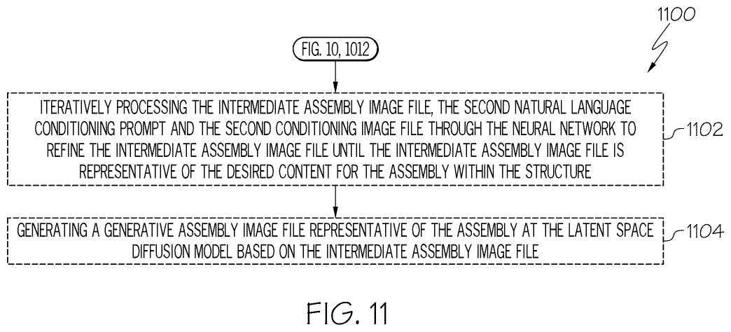

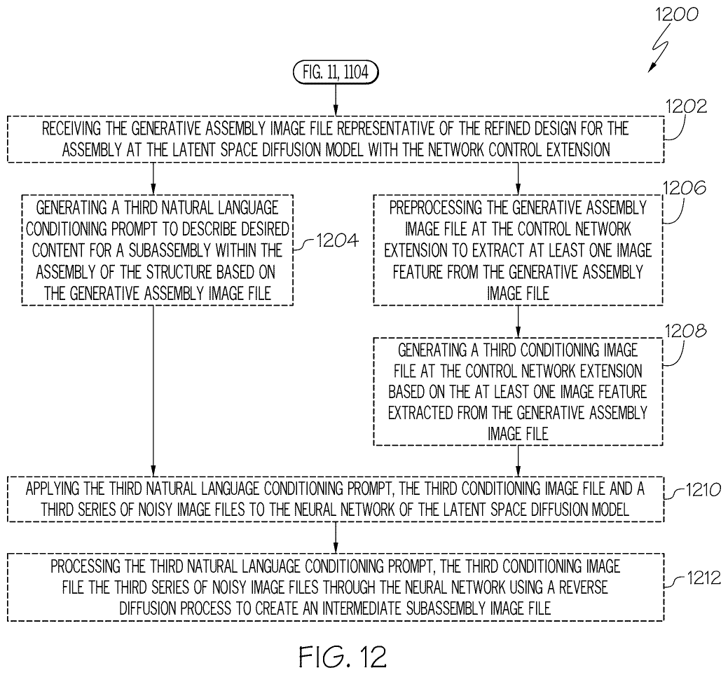

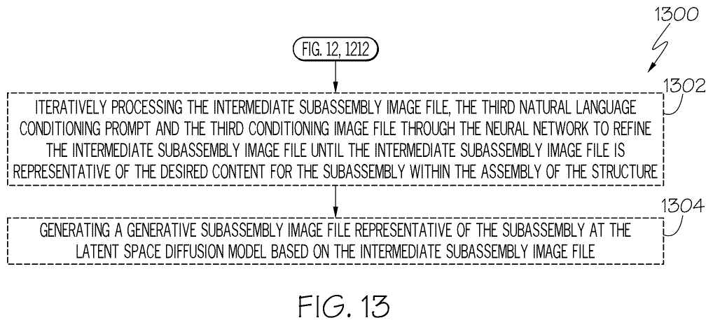

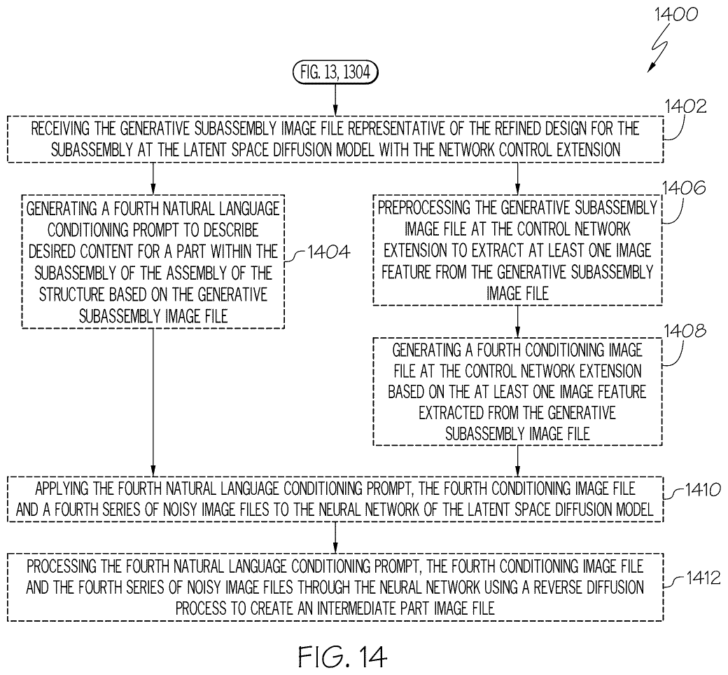

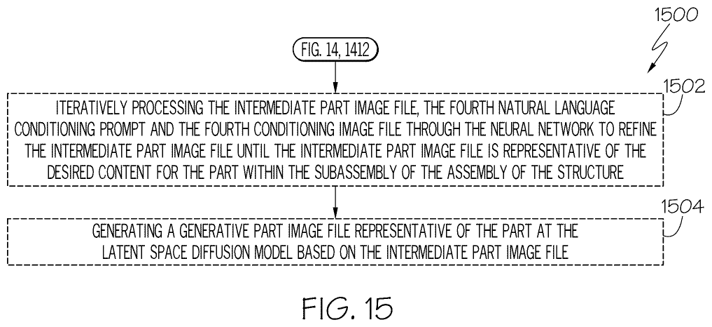

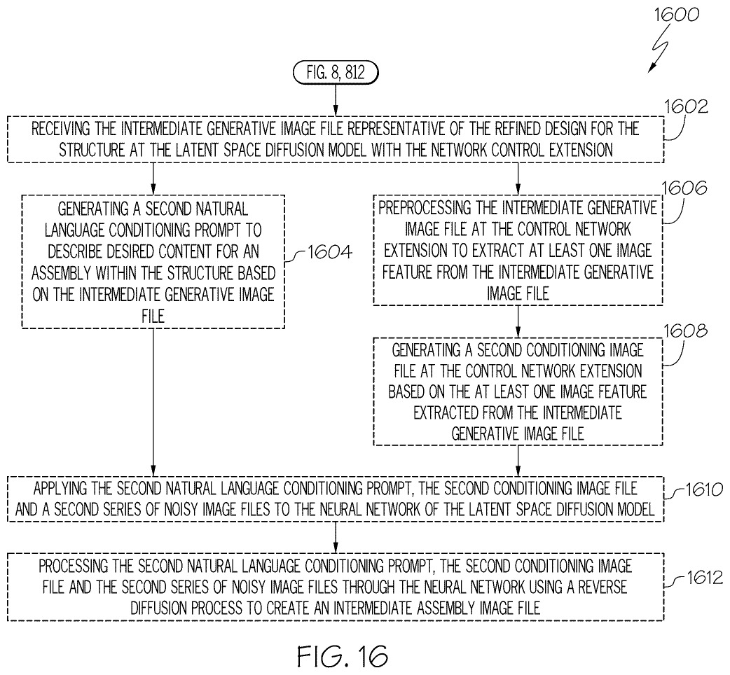

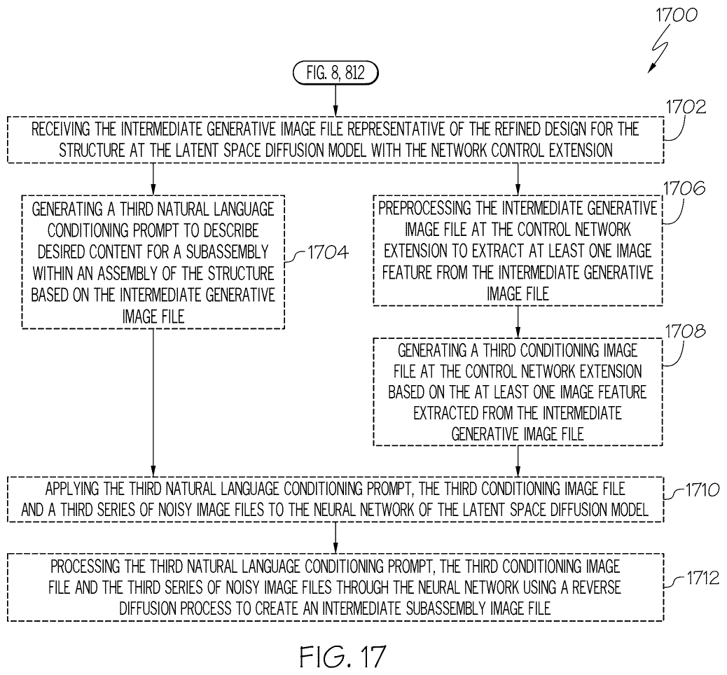

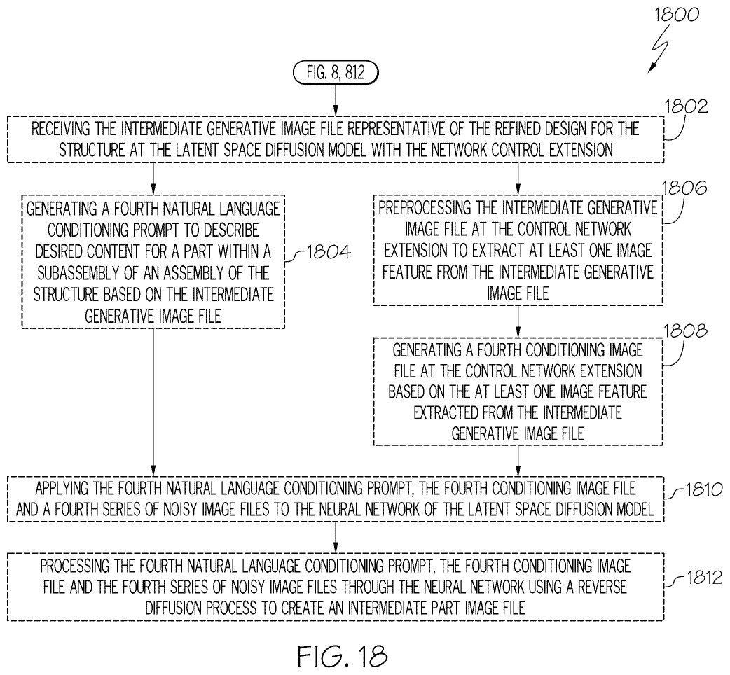

Referring generally to FIGS. 2, 8-18 and 20, by way of examples, the present disclosure is directed to a method 800, 900, 1000, 1100, 1200, 1300, 1400, 1500, 1600, 1700, 1800 for refining a topology optimized design 2002 of a structure 200. FIG. 2 is a top view of an example of the structure 200. FIG. 8 provides an example of the method 800 for refining the topology optimized design 2002 of the structure 200. FIG. 9, in combination with FIG. 8, provides an example of the method 900. FIG. 10, in combination with FIG. 8, provides an example of the method 1000. FIG. 11, in combination with FIG. 8, provides an example of the method 1100. FIG. 12, in combination with FIG. 8, provides an example of the method 1200. FIG. 13, in combination with FIG. 8, provides an example of the method 1300. FIG. 14, in combination with FIG. 8, provides an example of the method 1400. FIG. 15, in combination with FIG. 8, provides an example of the method 1500. FIG. 16, in combination with FIG. 8, provides an example of the method 1600. FIG. 17, in combination with FIG. 8, provides an example of the method 1700. FIG. 18, in combination with FIG. 1, provides an example of the method 1800. FIG. 20 is a block diagram of an example of a computerized system 2000 for refining the topology optimized design 2002 of the structure 200.

With reference again to FIGS. 2, 8 and 20, in one or more examples, a method 100 (sec FIG. 8) for refining a topology optimized design 2002 of a structure 200 includes receiving 802 a source image file 2004 representative of the topology optimized design 2002 for the structure 200 at a latent space diffusion model 2006 with a network control extension 2008. At 804, a natural language conditioning prompt 2010 is generated to describe desired content for a refined design of the structure 200 based on the topology optimized design 2002. At 806, the source image file 2004 is preprocessed at the network control extension 2008 using feature extraction tools 2012 to extract at least one image feature from the source image file 2004. At 808, a conditioning image file 2014 is generated at the network control extension 2008 based on the at least one image feature extracted from the source image file 2004. At 810, the natural language conditioning prompt 2010, the conditioning image file 2014 and a series of noisy image files 2016 are applied to a neural network 2018 of the latent space diffusion model 2006. The series of noisy image files 2016 is related to the source image file 2004. At 812, the natural language conditioning prompt 2010, the conditioning image file 2014 and the series of noisy image files 2016 are processed through the neural network 2018 using a reverse diffusion process 2020 to create an intermediate generative image file 2022.

In another example of the method 800, the source image file 2004 includes a two-dimensional view of the structure 200. In this example, the two-dimensional view includes an external view of the structure 200, a sectional view of the structure 200, a cross-sectional view of the structure 200, a truncated view of the structure 200 or any other suitable two-dimensional view in any suitable combination. In yet another example of the method 800, the source image file 2004 includes a two-dimensional view of the structure 200. In this example, the two-dimensional view includes any view of the structure 200, including, but not limited to, an external view, a sectional view, a cross-sectional view and a truncated view. In still another example of the method 800, the topology optimized design 2002 includes a three-dimensional model of the structure 200. In this example, the three-dimensional model of the structure 200 includes a computer-aided design model, a wireframe model, a surface model and a textured surface model. In still yet another example of the method 800, the topology optimized design 2002 includes a three-dimensional model of the structure 200. In this example, the three-dimensional model of the structure 200 includes any type of three-dimensional representation, including, but not limited to, a computer-aided design model, a wireframe model, a surface model and a textured surface model.

In another example of the method 800, the at least one image feature includes a pose feature, a background feature, a foreground feature, a depth feature, an edge feature, a line feature, a straight-line feature, an object feature, a texture feature, a color feature, a transparency feature or any other suitable image feature in any suitable combination. In yet another example of the method 800, the at least one image feature includes any type of visual characteristic or attribute of an image. In still another example of the method 800, the series of noisy image files 2016 are obtained from the source image file 2004 by adding a predetermined amount of noise to a first noisy image file and adding more noise to successive image files in the series such that a last noisy image file in the series includes a highest amount of noise. In still yet another example of the method 800, the series of noisy image files 2016 are obtained from the source image file 2004 by subtracting a predicted amount of noise from a first noisy image file and iteratively subtracting more noise to successive image files in the series such that a last noisy image file in the series includes a least amount of noise.

With reference again to FIGS. 2, 8, 9 and 20, in one or more examples, a method 900 (see FIG. 9) for refining a topology optimized design 2002 of a structure 200 includes the method 800 of FIG. 8 and continues from 812 to 902 where the intermediate generative image file 2022, the natural language conditioning prompt 2010 and the conditioning image file 2014 are iteratively processed through the neural network 2018 to refine the intermediate generative image file 2022 until the intermediate generative image file 2022 is representative of the desired content for the refined design of the structure 200. At 904, a refined generative image file 2026 representative of the refined design for the structure 200 is generated at the latent space diffusion model 2006 based on a final iteration of the intermediate generative image file 2022.

With reference again to FIGS. 2, 8-10 and 20, in one or more examples, a method 1000 (see FIG. 10) for refining a topology optimized design 2002 of a structure 200 includes the method 800 of FIG. 8, the method 900 of FIG. 9 and continues from 904 to 1002 where the refined generative image file 2026 representative of the refined design for the structure 200 is received at the latent space diffusion model 2006 with the network control extension 2008. At 1004, a second natural language conditioning prompt 2028 is generated to describe desired content for an assembly 202 within the structure 200 based on the refined generative image file 2026. At 1006, the refined generative image file 2026 is preprocessed at the network control extension 2008 using the feature extraction tools 2012 to extract at least one image feature from the refined generative image file 2026. At 1008, a second conditioning image file 2030 is generated at the network control extension 2008 based on the at least one image feature extracted from the refined generative image file 2026. At 1010, the second natural language conditioning prompt 2028, the second conditioning image file 2030 and a second series of noisy image files 2032 are applied to the neural network 2018 of the latent space diffusion model 2006. The second series of noisy image files 2032 is related to the refined generative image file 2026. At 1012, the second natural language conditioning prompt 2028, the second conditioning image file 2030 and the second series of noisy image files 2032 are processed through the neural network 2018 using the reverse diffusion process 2020 to create an intermediate assembly image file 2034.

With reference again to FIGS. 2, 8-11 and 20, in one or more examples, a method 1100 (see FIG. 11) for refining a topology optimized design 2002 of a structure 200 includes the method 800 of FIG. 8, the method 900 of FIG. 9, the method 1000 of FIG. 10 and continues from 1012 to 1102 where the intermediate assembly image file 2034, the second natural language conditioning prompt 2028 and the second conditioning image file 2030 are iteratively processed through the neural network 2018 to refine the intermediate assembly image file 2034 until the intermediate assembly image file 2034 is representative of the desired content for the assembly 202 within the structure 200. At 1104, a generative assembly image file 2036 representative of the assembly 202 is generated at the latent space diffusion model 2006 based on the intermediate assembly image file 2034.

With reference again to FIGS. 2, 8-12 and 20, in one or more examples, a method 1200 (see FIG. 12) for refining a topology optimized design 2002 of a structure 200 includes the FIG. 11 and continues from 1104 to 1202 where the generative assembly image file 2036 representative of the refined design for the assembly 202 is received at the latent space diffusion model 2006 with the network control extension 2008. At 1204, a third natural language conditioning prompt 2038 is generated to describe desired content for a subassembly 204 within the assembly 202 of the structure 200 based on the generative assembly image file 2036. At 1206, the generative assembly image file 2036 is preprocessed at the network control extension 2008 using the feature extraction tools 2012 to extract at least one image feature from the generative assembly image file 2036. At 1208, a third conditioning image file 2040 is generated at the network control extension 2008 based on the at least one image feature extracted from the generative assembly image file 2036. At 1210, the third natural language conditioning prompt 2038, the third conditioning image file 2040 and a third series of noisy image files 2042 are applied to the neural network 2018 of the latent space diffusion model 2006. The third series of noisy image files 2042 is related to the generative assembly image file 2036. At 1212, the third natural language conditioning prompt 2038, the third conditioning image file 2040 and the third series of noisy image files 2042 are processed through the neural network 2018 using the reverse diffusion process 2020 to create an intermediate subassembly image file 2044.

With reference again to FIGS. 2, 8-13 and 20, in one or more examples, a method 1300 (see FIG. 13) for refining a topology optimized design 2002 of a structure 200 includes the method 800 of FIG. 8, the method 900 of FIG. 9, the method 1000 of FIG. 10, the method 1100 of FIG. 11, the method 1200 of FIG. 12 and continues from 1212 to 1302 where the intermediate subassembly image file 2044, the third natural language conditioning prompt 2038 and the third conditioning image file 2040 are iteratively processed through the neural network 2018 to refine the intermediate subassembly image file 2044 until the intermediate subassembly image file 2044 is representative of the desired content for the subassembly 204 within the assembly 202 of the structure 200. At 1304, a generative subassembly image file 2046 representative of the subassembly 204 is generated at the latent space diffusion model 2006 based on the intermediate subassembly image file 2044.

With reference again to FIGS. 2, 8-14 and 20, in one or more examples, a method 1400 (see FIG. 14) for refining a topology optimized design 2002 of a structure 200 includes the FIG. 11, the method 1200 of FIG. 12, the method 1300 of FIG. 13 and continues from 1304 to 1402 where the generative subassembly image file 2046 representative of the refined design for the subassembly 204 is received at the latent space diffusion model 2006 with the network control extension 2008. At 1404, a fourth natural language conditioning prompt 2048 is generated to describe desired content for a part 206 within the subassembly 204 of the assembly 202 of the structure 200 based on the generative subassembly image file 2046. At 1406, the generative subassembly image file 2046 is preprocessed at the network control extension 2008 using the feature extraction tools 2012 to extract at least one image feature from the generative subassembly image file 2046. At 1408, a fourth conditioning image file 2050 is generated at the network control extension 2008 based on the at least one image feature extracted from the generative subassembly image file 2046. At 1410, the fourth natural language conditioning prompt 2048, the fourth conditioning image file 2050 and a fourth series of noisy image files 2052 are applied to the neural network 2018 of the latent space diffusion model 2006. The fourth series of noisy image files 2052 is related to the generative subassembly image file 2046. At 1412, the fourth natural language conditioning prompt 2048, the fourth conditioning image file 2050 and the fourth series of noisy image files 2052 are processed through the neural network 2018 using the reverse diffusion process 2020 to create an intermediate part image file 2054.

With reference again to FIGS. 2, 8-15 and 20, in one or more examples, a method 1500 (see FIG. 15) for refining a topology optimized design 2002 of a structure 200 includes the method 800 of FIG. 8, the method 900 of FIG. 9, the method 1000 of FIG. 10, the method 1100 of FIG. 11, the method 1200 of FIG. 12, the method 1300 of FIG. 13, the method 1400 of FIG. 14 and continues from 1412 to 1502 where the intermediate part image file 2054, the fourth natural language conditioning prompt 2048 and the fourth conditioning image file 2050 are iteratively processed through the neural network 2018 to refine the intermediate part image file 2054 until the intermediate part image file 2054 is representative of the desired content for the part 206 within the subassembly 204 of the assembly 202 of the structure 200. At 1504, a generative part image file 2056 representative of the part 206 is generated at the latent space diffusion model 2006 based on the intermediate part image file 2054.

With reference again to FIGS. 2, 8, 16 and 20, in one or more examples, a method 1600 (see FIG. 16) for refining a topology optimized design 2002 of a structure 200 includes the method 800 of FIG. 8 and continues from 812 to 1602 where the intermediate generative image file 2022 representative of the refined design for the structure 200 is received at the latent space diffusion model 2006 with the network control extension 2008. At 1604, a second natural language conditioning prompt 2028 is generated to describe desired content for an assembly 202 within the structure 200 based on the intermediate generative image file 2022. At 1606, the intermediate generative image file 2022 is preprocessed at the network control extension 2008 using the feature extraction tools 2012 to extract at least one image feature from the intermediate generative image file 2022. At 1608, a second conditioning image file 2030 is generated at the network control extension 2008 based on the at least one image feature extracted from the intermediate generative image file 2022. At 1610, the second natural language conditioning prompt 2028, the second conditioning image file 2030 and a second series of noisy image files 2032 are applied to the neural network 2018 of the latent space diffusion model 2006. The second series of noisy image files 2032 is related to the intermediate generative image file 2022. At 1612, the second natural language conditioning prompt 2028, the second conditioning image file 2030 and the second series of noisy image files 2032 are processed through the neural network 2018 using the reverse diffusion process 2020 to create an intermediate assembly image file 2034. In another example of the method 1600, the at least one image feature includes a pose feature, a background feature, a foreground feature, a depth feature, an edge feature, a line feature, a straight-line feature, an object feature, a texture feature, a color feature and a transparency feature.

With reference again to FIGS. 2, 8, 17 and 20, in one or more examples, a method 1700 (see FIG. 17) for refining a topology optimized design 2002 of a structure 200 includes the method 800 of FIG. 8 and continues from 812 to 1702 where the intermediate generative image file 2022 representative of the refined design for the structure 200 is received at the latent space diffusion model 2006 with the network control extension 2008. At 1704, a third natural language conditioning prompt 2038 is generated to describe desired content for a subassembly 204 within an assembly 202 of the structure 200 based on the intermediate generative image file 2022. At 1706, the intermediate generative image file 2022 is processed at the network control extension 2008 using the feature extraction tools 2012 to extract at least one image feature from the intermediate generative image file 2022. At 1708, a third conditioning image file 2040 is generated at the network control extension 2008 based on the at least one image feature extracted from the intermediate generative image file 2022. At 1710, the third natural language conditioning prompt 2038, the third conditioning image file 2040 and a third series of noisy image files 2042 are applied to the neural network 2018 of the latent space diffusion model 2006. The third series of noisy image files 2042 is related to the intermediate generative image file 2022. At 1712, the third natural language conditioning prompt 2038, the third conditioning image file 2040 and the third series of noisy image files 2042 are processed through the neural network 2018 using the reverse diffusion process 2020 to create an intermediate subassembly image file 2044. In another example of the method 1700, the at least one image feature includes a pose feature, a background feature, a foreground feature, a depth feature, an edge feature, a line feature, a straight-line feature, an object feature, a texture feature, a color feature and a transparency feature.

With reference again to FIGS. 2, 8, 18 and 20, in one or more examples, a method 1800 (see FIG. 18) for refining a topology optimized design 2002 of a structure 200 includes the method 800 of FIG. 8 and continues from 812 to 1802 where the intermediate generative image file 2022 representative of the refined design for the structure 200 is received at the latent space diffusion model 2006 with the network control extension 2008. At 1804, a fourth natural language conditioning prompt 2048 is generated to describe desired content for a part 206 within a subassembly 204 of an assembly 202 of the structure 200 based on the intermediate generative image file 2022. At 1806, the intermediate generative image file 2022 is preprocessed at the network control extension 2008 using the feature extraction tools 2012 to extract at least one image feature from the intermediate generative image file 2022. At 1808, a fourth conditioning image file 2050 is generated at the network control extension 2008 based on the at least one image feature extracted from the intermediate generative image file 2022. At 1810, the fourth natural language conditioning prompt 2048, the fourth conditioning image file 2050 and a fourth series of noisy image files 2052 are applied to the neural network 2018 of the latent space diffusion model 2006. The fourth series of noisy image files 2052 is related to the intermediate generative image file 2022. At 1812, the fourth natural language conditioning prompt 2048, the fourth conditioning image file 2050 and the fourth series of noisy image files 2052 are processed through the neural network 2018 using the reverse diffusion process 2020 to create an intermediate part image file 2054. In another example of the method 1800, the at least one image feature includes a pose feature, a background feature, a foreground feature, a depth feature, an edge feature, a line feature, a straight-line feature, an object feature, a texture feature, a color feature and a transparency feature.

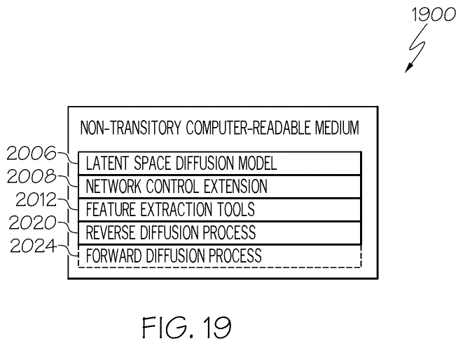

Referring generally to FIGS. 1-7, 19 and 20, by way of examples, the present disclosure is directed to a non-transitory computer-readable medium 1900 including program instructions that, when executed by at least one processor 2058, cause at least one computing device 2060 to perform a method 100, 300, 400, 500, 600, 700 for refining a topology optimized design 2002 of a structure 200. FIG. 1 provides an example of the method 100 for refining the topology optimized design 2002 of the structure 200. FIG. 2 is a top view of an example of the structure 200. FIG. 3, in combination with FIG. 1, provides an example of the method 300. FIG. 4, in combination with FIG. 1, provides an example of the method 400. FIG. 5, in combination with FIG. 1, provides an example of the method 500. FIG. 6, in combination with FIG. 1, provides an example of the method 600. FIG. 7, in combination with FIG. 1, provides an example of the method 700. FIG. 19 is a block diagram of an example of the non-transitory computer-readable medium 1900. FIG. 20 is a block diagram of an example of a computerized system 2000 for refining the topology optimized design 2002 of the structure 200.

With reference again to FIGS. 1-7, 19 and 20, in one or more examples, a non-transitory computer-readable medium 1900 is disclosed. The non-transitory computer-readable medium 1900 includes program instructions that, when executed by at least one processor 2058, cause at least one computing device 2060 to perform a method 100, 300, 400, 500, 600, 700 for refining a topology optimized design 2002 of a structure 200.

In one or more examples, the method 100 (see FIG. 1) includes receiving 102 a source image file 2004 representative of the topology optimized design 2002 for the structure 200 at a latent space diffusion model 2006 with a network control extension 2008. At 104, a natural language conditioning prompt 2010 is generated to describe desired content for a refined design of the structure 200 based on the topology optimized design 2002. At 106 the source image file 2004 is preprocessed at the network control extension 2008 using feature extraction tools 2012 to extract image features from the source image file 2004. At 108, a conditioning image file 2014 is generated at the network control extension 2008 based on the image features extracted from the source image file 2004. At 110, the natural language conditioning prompt 2010, the conditioning image file 2014 and a series of noisy image files 2016 to a neural network 2018 of the latent space diffusion model 2006. At 112, the natural language conditioning prompt 2010, the conditioning image file 2014 and the series of noisy image files 2016 through the neural network 2018 using a reverse diffusion process 2020 to create an intermediate generative image file 2022.

In one or more example, the method 300 (see FIG. 3) includes the method 100 of FIG. 1 and continues from 102 to 302 where the source image file 2004 is preprocessed at the latent space diffusion model 2006 using a forward diffusion process 2024 to obtain the series of noisy image files 2016 in which a level of noise in the series of noisy image files 2016 ranges from less noise in a first noisy image file to more noise in successive image files such that a last noisy image file in the series includes a highest amount of noise. The method 300 continues from 302 to 110 of FIG. 1.

In one or more example, the method 400 (see FIG. 4) includes the method 100 of FIG. 1 and continues from 112 to 402 where the intermediate generative image file 2022, the natural language conditioning prompt 2010 and the conditioning image file 2014 are iteratively processed through the neural network 2018 to refine the intermediate generative image file 2022 until the intermediate generative image file 2022 is representative of the desired content for the refined design of the structure 200. In another example, the method 400 also includes generating 404 a refined generative image file 2026 representative of the refined design for the structure 200 at the latent space diffusion model 2006 based on a final iteration of the intermediate generative image file 2022.

In one or more example, the method 500 (see FIG. 5) includes the method 100 of FIG. 1 and continues from 112 to 502 where the intermediate generative image file 2022 is compared to the source image file 2004 and the desired content. At 504, a second natural language conditioning prompt 2028 is generated to describe further desired content for the refined design of the structure 200 based on the comparing. At 506, the intermediate generative image file 2022, the second natural language conditioning prompt 2028 and the conditioning image file 2014 are iteratively processed through the neural network 2018 to refine the intermediate generative image file 2022 until the intermediate generative image file 2022 is representative of the further desired content for the refined design of the structure 200.

In one or more example, the method 600 (see FIG. 6) includes the method 100 of FIG. 1 and continues from 112 to 602 where the intermediate generative image file 2022 is compared to the source image file 2004 and the desired content. At 604, the source image file 2004 is preprocessed at the network control extension 2008 using the feature extraction tools 2012 to extract second image features from the source image file 2004. At 606, a second conditioning image file 2030 is generated at the network control extension 2008 based on the second image features extracted from the source image file 2004. At 608, the intermediate generative image file 2022, the natural language conditioning prompt 2010 and the second conditioning image file 2030 are iteratively processed through the neural network 2018 to refine the intermediate generative image file 2022 until the intermediate generative image file 2022 is representative of the desired content for the refined design of the structure 200.

In one or more example, the method 700 (see FIG. 7) includes the method 100 of FIG. 1 and continues from 112 to 702 where the intermediate generative image file 2022 is compared to the source image file 2004 and the desired content. At 704, the intermediate generative image file 2022 is preprocessed at the network control extension 2008 using the feature extraction tools 2012 to extract second image features from the intermediate generative image file 2022. At 706, a second conditioning image file 2030 is generated at the network control extension 2008 based on the second image features extracted from the intermediate generative image file 2022. At 708, the intermediate generative image file 2022, the natural language conditioning prompt 2010 and the second conditioning image file 2030 are iteratively processed through the neural network 2018 to refine the intermediate generative image file 2022 until the intermediate generative image file 2022 is representative of the desired content for the refined design of the structure 200.

With reference again to FIG. 20, a computerized system 2000 includes at least one computing device 2060. The at least one computing device 2060 includes a neural network 2018, at least one processor 2058 and associated memory 2059, at least one application program storage device 2062, at least one data storage device 2064, and a network interface 2066. The at least one computing device 2060 may also include an input device 2068 and a display device 2070. The at least one processor 2058 is in operative communication with a design data repository 2072 through a communication network 2074 via the network interface 2066. The design data repository 2072 may include a topology optimized design 2002 and a source image file 2004.

Examples of methods 100, 300, 400, 500, 600, 700, 800, 900, 1000, 1100, 1200, 1300, 1400, 1500, 1600, 1700, 1800 for refining topology optimized designs 2002 of structures 200 and non-transitory computer-readable media 1900 associated therewith may be related to or used in the context of aircraft design and manufacture. Although an aircraft example is described, the examples and principles disclosed herein may be applied to other products in the aerospace industry and other industries, such as the automotive industry, the space industry, the construction industry and other design and manufacturing industries. Accordingly, in addition to aircraft, the examples and principles disclosed herein may apply to methods for design and manufacture of various types of vehicles and in the design and construction of various types of transportation structures.

The preceding detailed description refers to the accompanying drawings, which illustrate specific examples described by the present disclosure. Other examples having different structures and operations do not depart from the scope of the present disclosure. Like reference numerals may refer to the same feature, element, or component in the different drawings. Throughout the present disclosure, any one of a plurality of items may be referred to individually as the item and a plurality of items may be referred to collectively as the items and may be referred to with like reference numerals. Moreover, as used herein, a feature, element, component, or step preceded with the word “a” or “an” should be understood as not excluding a plurality of features, elements, components, or steps, unless such exclusion is explicitly recited.

Illustrative, non-exhaustive examples, which may be, but are not necessarily, claimed, of the subject matter according to the present disclosure are provided above. Reference herein to “example” means that one or more feature, structure, element, component, characteristic, and/or operational step described in connection with the example is included in at least one aspect, embodiment, and/or implementation of the subject matter according to the present disclosure. Thus, the phrases “an example,” “another example,” “one or more examples,” and similar language throughout the present disclosure may, but do not necessarily, refer to the same example. Further, the subject matter characterizing any one example may, but does not necessarily, include the subject matter characterizing any other example. Moreover, the subject matter characterizing any one example may be, but is not necessarily, combined with the subject matter characterizing any other example.

As used herein, a system, apparatus, control system, device, computing device, processor, structure, article, element, component, or hardware “configured to” perform a specified function is indeed capable of performing the specified function without any alteration, rather than merely having potential to perform the specified function after further modification. In other words, the system, apparatus, device, control system, computing device, processor, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, control system, device, computing device, processor, structure, article, element, component, or hardware that enable the system, apparatus, control system, device, computing device, processor, structure, article, element, component, or hardware to perform the specified function without further modification. For purposes of this disclosure, a system, apparatus, device, control system, device, computing device, processor, structure, article, element, component, or hardware described as being “configured to” perform a particular function may additionally or alternatively be described as being “adapted to” and/or as being “operative to” perform that function.

Unless otherwise indicated, the terms “first,” “second,” “third,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

As used herein, the phrase “at least one of,” when used with a list of items, means different combinations of one or more of the listed items may be used and only one of each item in the list may be needed. For example, “at least one of item A, item B, and item C” may include, without limitation, item A or item A and item B. This example also may include item A, item B, and item C, or item B and item C. In other examples, “at least one of” may be, for example, without limitation, two of item A, one of item B, and ten of item C; four of item B and seven of item C; and other suitable combinations. As used herein, the term “and/or” and the “/” symbol includes any and all combinations of one or more of the associated listed items.

As used herein, the terms “coupled,” “coupling,” and similar terms refer to two or more elements that are joined, linked, fastened, attached, connected, put in communication, or otherwise associated (e.g., mechanically, electrically, fluidly, optically, electromagnetically) with one another. In various examples, the elements may be associated directly or indirectly. As an example, clement A may be directly associated with element B. As another example, element A may be indirectly associated with element B, for example, via another element C. It will be understood that not all associations among the various disclosed elements are necessarily represented. Accordingly, couplings other than those depicted in the figures may also exist.

As used herein, the term “approximately” refers to or represents a condition that is close to, but not exactly, the stated condition that still performs the desired function or achieves the desired result. As an example, the term “approximately” refers to a condition that is within an acceptable predetermined tolerance or accuracy, such as to a condition that is within 10% of the stated condition. However, the term “approximately” does not exclude a condition that is exactly the stated condition. As used herein, the term “substantially” refers to a condition that is essentially the stated condition that performs the desired function or achieves the desired result.

In FIGS. 1, 3-18 and 21-23, referred to above, the blocks may represent operations, steps, and/or portions thereof, and lines connecting the various blocks do not imply any particular order or dependency of the operations or portions thereof. It will be understood that not all dependencies among the various disclosed operations are necessarily represented. FIGS. 1, 3-18 and 21-23 and the accompanying disclosure describing the operations of the disclosed methods set forth herein should not be interpreted as necessarily determining a sequence in which the operations are to be performed. Rather, although one illustrative order is indicated, it is to be understood that the sequence of the operations may be modified when appropriate. Accordingly, modifications, additions and/or omissions may be made to the operations illustrated and certain operations may be performed in a different order or simultaneously. Additionally, those skilled in the art will appreciate that not all operations described need be performed.

FIGS. 2, 19 and 20, referred to above, may represent functional elements, features, or components thereof and do not necessarily imply any particular structure. Accordingly, modifications, additions and/or omissions may be made to the illustrated structure. Additionally, those skilled in the art will appreciate that not all elements, features, and/or components described and illustrated in FIGS. 2, 19 and 20, referred to above, need be included in every example and not all elements, features, and/or components described herein are necessarily depicted in each illustrative example. Accordingly, some of the elements, features, and/or components described and illustrated in FIGS. 2, 19 and 20 may be combined in various ways without the need to include other features described and illustrated in FIGS. 2, 19 and 20, other drawing figures, and/or the accompanying disclosure, even though such combination or combinations are not explicitly illustrated herein. Similarly, additional features not limited to the examples presented, may be combined with some or all the features shown and described herein. Unless otherwise explicitly stated, the schematic illustrations of the examples depicted in FIGS. 2, 19 and 20, referred to above, are not meant to imply structural limitations with respect to the illustrative example. Rather, although one illustrative structure is indicated, it is to be understood that the structure may be modified when appropriate. Accordingly, modifications, additions and/or omissions may be made to the illustrated structure. Furthermore, elements, features, and/or components that serve a similar, or at least substantially similar, purpose are labeled with like numbers in each of FIGS. 2, 19 and 20, and such elements, features, and/or components may not be discussed in detail herein with reference to each of FIGS. 2, 19 and 20. Similarly, all elements, features, and/or components may not be labeled in each of FIGS. 2, 19 and 20, but reference numerals associated therewith may be utilized herein for consistency.

Further, references throughout the present specification to features, advantages, or similar language used herein do not imply that all the features and advantages that may be realized with the examples disclosed herein should be, or are in, any single example. Rather, language referring to the features and advantages is understood to mean that a specific feature, advantage, or characteristic described in connection with an example is included in at least one example. Thus, discussion of features, advantages, and similar language used throughout the present disclosure may, but does not necessarily, refer to the same example.

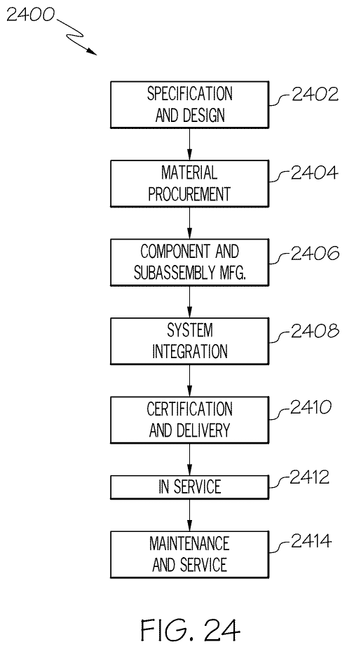

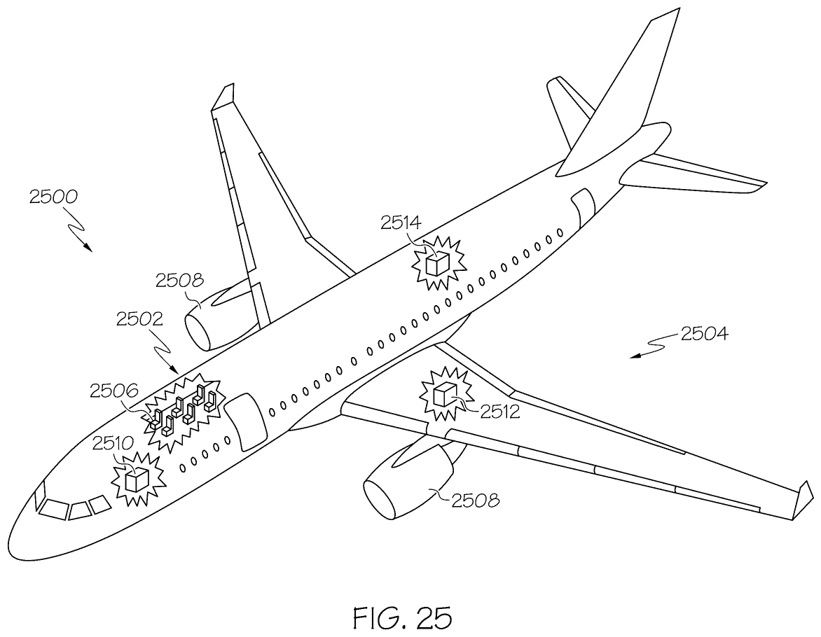

Examples of the subject matter disclosed herein may be described in the context of aircraft manufacturing and service method 2400 as shown in FIG. 24 and aircraft 2500 as shown in FIG. 25. In one or more examples, the disclosed methods 100, 300, 400, 500, 600, 700, 800, 900, 1000, 1100, 1200, 1300, 1400, 1500, 1600, 1700, 1800 for refining topology optimized designs 2002 of structures 200 and non-transitory computer-readable media 1900 associated therewith may be used in aircraft manufacturing. During pre-production, the service method 2400 may include specification and design (block 2402) of aircraft 2500 and material procurement (block 2404). During production, component and subassembly manufacturing (block 2406) and system integration (block 2408) of aircraft 2500 may take place. Thereafter, aircraft 2500 may go through certification and delivery (block 2410) to be placed in service (block 2412). While in service, aircraft 2500 may be scheduled for routine maintenance and service (block 2414). Routine maintenance and service may include modification, reconfiguration, refurbishment, etc. of one or more systems of aircraft 2500.

Each of the processes of the service method 2400 may be performed or carried out by a system integrator, a third party, and/or an operator (e.g., a customer). For the purposes of this description, a system integrator may include, without limitation, any number of aircraft manufacturers and major-system subcontractors; a third party may include, without limitation, any number of vendors, subcontractors, and suppliers; and an operator may be an airline, leasing company, military entity, service organization, and so on.

As shown in FIG. 25, aircraft 2500 produced by the service method 2400 may include airframe 2502 with a plurality of high-level systems 2504 and interior 2506. Examples of high-level systems 2504 include one or more of propulsion system 2508, electrical system 2510, hydraulic system 2512, and environmental system 2514. Any number of other systems may be included. Although an aerospace example is shown, the principles disclosed herein may be applied to other industries, such as the automotive industry. Accordingly, in addition to aircraft 2500, the principles disclosed herein may apply to other vehicles, e.g., land vehicles, marine vehicles, space vehicles, etc.

The disclosed methods 100, 300, 400, 500, 600, 700, 800, 900, 1000, 1100, 1200, 1300, 1400, 1500, 1600, 1700, 1800 for refining topology optimized designs 2002 of structures 200 and non-transitory computer-readable media 1900 associated therewith may be employed during any one or more of the stages of the manufacturing and service method 2400. For example, components or subassemblies corresponding to component and subassembly manufacturing (block 2406) may be fabricated or manufactured in a manner similar to components or subassemblies produced while aircraft 2500 is in service (block 2412). Also, one or more examples of the tooling set(s), system(s), method(s), or any combination thereof may be utilized during production stages (block 2406 and block 2408), for example, by substantially expediting assembly of or reducing the cost of aircraft 2500. Similarly, one or more examples of the tooling set, system or method realizations, or a combination thereof, may be utilized, for example and without limitation, while aircraft 2500 is in service (block 2412) and/or during maintenance and service (block 2414).

The described features, advantages, and characteristics of one example may be combined in any suitable manner in one or more other examples. One skilled in the relevant art will recognize that the examples described herein may be practiced without one or more of the specific features or advantages of a particular example. In other instances, additional features and advantages may be recognized in certain examples that may not be present in all examples. Furthermore, although various examples of the methods 100, 300, 400, 500, 600, 700, 800, 900, 1000, 1100, 1200, 1300, 1400, 1500, 1600, 1700, 1800 for refining topology optimized designs 2002 of structures 200 and non-transitory computer-readable media 1900 associated therewith have been shown and described, modifications may occur to those skilled in the art upon reading the specification. The present application includes such modifications and is limited only by the scope of the claims.

1. A method for refining a topology optimized design of a structure, comprising:
receiving a source image file representative of the topology optimized design for the structure at a latent space diffusion model with a network control extension;
generating a natural language conditioning prompt to describe desired content for a refined design of the structure based on the topology optimized design;
preprocessing the source image file at the network control extension using feature extraction tools to extract image features from the source image file;
generating a conditioning image file at the network control extension based on the image features extracted from the source image file;
applying the natural language conditioning prompt, the conditioning image file and a series of noisy image files to a neural network of the latent space diffusion model; and
processing the natural language conditioning prompt, the conditioning image file and the series of noisy image files through the neural network using a reverse diffusion process to create an intermediate generative image file.

2-7. (canceled)

8. The method of claim 1 wherein the image features comprise at least one of pose features, background features, foreground features, depth features, edge features, line features, straight-line features, object features, texture features, color features and transparency features.

9-11. (canceled)

12. The method of claim 1, further comprising:
preprocessing the source image file at the latent space diffusion model using a forward diffusion process to obtain the series of noisy image files in which a level of noise in the series of noisy image files ranges from less noise in a first noisy image file to more noise in successive image files such that a last noisy image file in the series includes a highest amount of noise.

13. (canceled)

14. The method of claim 1, further comprising:
iteratively processing the intermediate generative image file, the natural language conditioning prompt and the conditioning image file through the neural network to refine the intermediate generative image file until the intermediate generative image file is representative of the desired content for the refined design of the structure.

15. The method of claim 14, further comprising:
generating a refined generative image file representative of the refined design for the structure at the latent space diffusion model based on a final iteration of the intermediate generative image file.

16-18. (canceled)

19. The method of claim 15 wherein the refined generative image file comprises an exploded view of the structure that shows at least two parts used to fabricate the structure in a disassembled representation.

20-21. (canceled)

22. The method of claim 1, further comprising:
processing the intermediate generative image file, the natural language conditioning prompt and the conditioning image file through the neural network in a non-iterative manner to refine the intermediate generative image file until the intermediate generative image file is representative of the desired content for the refined design of the structure.

23. The method of claim 1, further comprising:
comparing the intermediate generative image file to the source image file and the desired content;
generating a second natural language conditioning prompt to describe further desired content for the refined design of the structure based on the comparing; and
iteratively processing the intermediate generative image file, the second natural language conditioning prompt and the conditioning image file through the neural network to refine the intermediate generative image file until the intermediate generative image file is representative of the further desired content for the refined design of the structure.

24. The method of claim 1, further comprising:
generating natural language conditioning prompts to describe further desired content for the refined design of the structure based on intermediate results; and
refining design inputs based on iterative processing of the intermediate generative image file, the natural language conditioning prompt and the conditioning image file through the neural network until the intermediate generative image file is representative of the further desired content for the refined design of the structure.

25. The method of claim 1, further comprising:
comparing the intermediate generative image file to the source image file and the desired content;
preprocessing the source image file at the network control extension using the feature extraction tools to extract second image features from the source image file;
generating a second conditioning image file at the network control extension based on the second image features extracted from the source image file; and
iteratively processing the intermediate generative image file, the natural language conditioning prompt and the second conditioning image file through the neural network to refine the intermediate generative image file until the intermediate generative image file is representative of the desired content for the refined design of the structure.

26. The method of claim 1, further comprising:
generating conditioning images based on intermediate results; and
refining design inputs based on iterative processing of the intermediate generative image file, the natural language conditioning prompt and the conditioning image file through the neural network until the intermediate generative image file is representative of the desired content for the refined design of the structure.

27. The method of claim 1, further comprising:
comparing the intermediate generative image file to the source image file and the desired content;
preprocessing the intermediate generative image file at the network control extension using the feature extraction tools to extract second image features from the intermediate generative image file;
generating a second conditioning image file at the network control extension based on the second image features extracted from the intermediate generative image file; and
iteratively processing the intermediate generative image file, the natural language conditioning prompt and the second conditioning image file through the neural network to refine the intermediate generative image file until the intermediate generative image file is representative of the desired content for the refined design of the structure.

28. A method for refining a topology optimized design of a structure, comprising:
receiving a source image file representative of the topology optimized design for the structure at a latent space diffusion model with a network control extension;
generating a natural language conditioning prompt to describe desired content for a refined design of the structure based on the topology optimized design;
preprocessing the source image file at the network control extension using feature extraction tools to extract at least one image feature from the source image file;
generating a conditioning image file at the network control extension based on the at least one image feature extracted from the source image file;
applying the natural language conditioning prompt, the conditioning image file and a series of noisy image files to a neural network of the latent space diffusion model, wherein the series of noisy image files is related to the source image file; and
processing the natural language conditioning prompt, the conditioning image file and the series of noisy image files through the neural network using a reverse diffusion process to create an intermediate generative image file.

29-36. (canceled)

37. The method of claim 28, further comprising:
iteratively processing the intermediate generative image file, the natural language conditioning prompt and the conditioning image file through the neural network to refine the intermediate generative image file until the intermediate generative image file is representative of the desired content for the refined design of the structure; and
generating a refined generative image file representative of the refined design for the structure at the latent space diffusion model based on a final iteration of the intermediate generative image file.

38. The method of claim 37, further comprising:
receiving the refined generative image file representative of the refined design for the structure at the latent space diffusion model with the network control extension;
generating a second natural language conditioning prompt to describe desired content for an assembly within the structure based on the refined generative image file;
preprocessing the refined generative image file at the network control extension using the feature extraction tools to extract at least one image feature from the refined generative image file;
generating a second conditioning image file at the network control extension based on the at least one image feature extracted from the refined generative image file;
applying the second natural language conditioning prompt, the second conditioning image file and a second series of noisy image files to the neural network of the latent space diffusion model, wherein the second series of noisy image files is related to the refined generative image file; and
processing the second natural language conditioning prompt, the second conditioning image file and the second series of noisy image files through the neural network using the reverse diffusion process to create an intermediate assembly image file.

39. The method of claim 38, further comprising:
iteratively processing the intermediate assembly image file, the second natural language conditioning prompt and the second conditioning image file through the neural network to refine the intermediate assembly image file until the intermediate assembly image file is representative of the desired content for the assembly within the structure; and
generating a generative assembly image file representative of the assembly at the latent space diffusion model based on the intermediate assembly image file.

40-43. (canceled)

44. The method of claim 28, further comprising:
receiving the intermediate generative image file representative of the refined design for the structure at the latent space diffusion model with the network control extension;
generating a second natural language conditioning prompt to describe desired content for an assembly within the structure based on the intermediate generative image file;
preprocessing the intermediate generative image file at the network control extension using the feature extraction tools to extract at least one image feature from the intermediate generative image file;
generating a second conditioning image file at the network control extension based on the at least one image feature extracted from the intermediate generative image file;
applying the second natural language conditioning prompt, the second conditioning image file and a second series of noisy image files to the neural network of the latent space diffusion model, wherein the second series of noisy image files is related to the intermediate generative image file; and
processing the second natural language conditioning prompt, the second conditioning image file and the second series of noisy image files through the neural network using the reverse diffusion process to create an intermediate assembly image file.

45. (canceled)

46. The method of claim 28, further comprising:
receiving the intermediate generative image file representative of the refined design for the structure at the latent space diffusion model with the network control extension;
generating a third natural language conditioning prompt to describe desired content for a subassembly within an assembly of the structure based on the intermediate generative image file;
preprocessing the intermediate generative image file at the network control extension using the feature extraction tools to extract at least one image feature from the intermediate generative image file;
generating a third conditioning image file at the network control extension based on the at least one image feature extracted from the intermediate generative image file;
applying the third natural language conditioning prompt, the third conditioning image file and a third series of noisy image files to the neural network of the latent space diffusion model, wherein the third series of noisy image files is related to the intermediate generative image file; and
processing the third natural language conditioning prompt, the third conditioning image file and the third series of noisy image files through the neural network using the reverse diffusion process to create an intermediate subassembly image file.

47. (canceled)

48. The method of claim 28, further comprising:
receiving the intermediate generative image file representative of the refined design for the structure at the latent space diffusion model with the network control extension;
generating a fourth natural language conditioning prompt to describe desired content for a part within a subassembly of an assembly of the structure based on the intermediate generative image file;
preprocessing the intermediate generative image file at the network control extension using the feature extraction tools to extract at least one image feature from the intermediate generative image file;
generating a fourth conditioning image file at the network control extension based on the at least one image feature extracted from the intermediate generative image file;
applying the fourth natural language conditioning prompt, the fourth conditioning image file and a fourth series of noisy image files to the neural network of the latent space diffusion model, wherein the fourth series of noisy image files is related to the intermediate generative image file; and
processing the fourth natural language conditioning prompt, the fourth conditioning image file and the fourth series of noisy image files through the neural network using the reverse diffusion process to create an intermediate part image file.

49. (canceled)

50. A non-transitory computer-readable medium comprising program instructions that, when executed by at least one processor, cause at least one computing device to perform a method for refining a topology optimized design of a structure, the method comprising:
receiving a source image file representative of the topology optimized design for the structure at a latent space diffusion model with a network control extension;
generating a natural language conditioning prompt to describe desired content for a refined design of the structure based on the topology optimized design;
preprocessing the source image file at the network control extension using feature extraction tools to extract image features from the source image file;
generating a conditioning image file at the network control extension based on the image features extracted from the source image file;
applying the natural language conditioning prompt, the conditioning image file and a series of noisy image files to a neural network of the latent space diffusion model; and
processing the natural language conditioning prompt, the conditioning image file and the series of noisy image files through the neural network using a reverse diffusion process to create an intermediate generative image file.

51-56. (canceled)
